(19) United States
(12) Patent Application Publication
(10) Pub. No.: US 2008/0111934 A1
(43) Pub. Date: May 15, 2008

(54) TFT-LCD ARRAY SUBSTRATE AND MANUFACTURING METHOD THEREOF

(76) Inventors: Hongjiang Wu, Beijing (CN); Wei Wang, Beijing (CN); Chunping Long, Beijing (CN); Chang Hee Lee, Beijing (CN)

Correspondence Address: HASSE & NESBITT LLC, 8837 CHAPEL SQUARE DRIVE, SUITE C, CINCINNATI, OH, 45249, US

(21) Appl. No.: 11/938,431

(22) Filed: Nov. 12, 2007

(30) Foreign Application Priority Data
Nov. 10, 2006 (CN) CN 200610145111.7

(51) Int. Cl. G02F 1/133; G02F 1/1368; H01L 21/77

(52) U.S. Cl. 349/38; 349/46; 438/30; 257/E21.598

(57) ABSTRACT

A TFT-LCD array substrate and a method for manufacturing the same. The TFT-LCD array substrate includes a substrate, on which at least one gate line and at least one data line are formed and cross with each other to define sub-pixel regions, one of the sub-pixel regions includes a thin film transistor (TFT) and a pixel electrode, and the TFT is electrically connected to the pixel electrode. The TFT-LCD array substrate further includes a compensating parasitic capacitor structure comprising a first electrode electrically connected to the gate line and a second electrode electrically connected to the pixel electrode.

### FIELD OF THE INVENTION

The present invention relates to a thin film transistor liquid crystal display (TFT-LCD) array substrate and a manufacturing method thereof, and more particularly, to a TFT-LCD array substrate with a self-compensating parasitic capacitor structure and a manufacturing method thereof.

### BACKGROUND OF THE INVENTION

In a TFT-LCD, the display of images is realized by changing the transmittance of the pixel points arrayed on a panel. A TFT-LCD includes many pixels, each of which in turn is composed of, for example, three sub-pixels (for example, R, G, and B sub-pixels), and can display, for example, 256 or more levels in gray scale. To display a desired image, it is necessary to control the gray scale of each sub-pixel. Each sub-pixel is controlled by a thin film transistor (TFT) as a switching element. A TFT-LCD includes an array substrate, a color film substrate, and a liquid crystal layer interposed between the substrates.

On the array substrate, a plurality of gate lines in parallel and a plurality of data lines in parallel are arranged to cross with each other so as to define a plurality of sub-pixel areas. FIG. 1 is the circuit diagram of a single sub-pixel of the TFT-LCD. As shown in FIG. 1, in the horizontal direction, N represents the n^{th} gate line, and N+1 represents the (n+1)^{th} gate line; in the vertical direction, M represents the m^{th} data line, and M+1 represents the (m+1)^{th} data line, wherein m and n are integers larger than 1. T represents the TFT that is used as the switching element for the sub-pixel. The gate electrode of the TFT is connected to the (n+1)^{th} gate line, the drain electrode is connected to the m^{th} data line, and the source electrode is connected to the pixel electrode of the sub-pixel. In this circuit diagram, a parasitic capacitor Cgs, a liquid crystal capacitor Clc, and a storage capacitor Cst are also shown.

When a turn-on voltage (Von) is applied to the gate of the sub-pixel to turn on the TFT, a conduction path is formed between the source and the drain electrodes of the TFT, and a given signal is applied to the pixel electrode of the sub-pixel from the data line. In case that the voltage of an opposing electrode arranged on the color film substrate is constant, the voltage applied to the pixel electrode of the sub-pixel determines the gray scale of the corresponding sub-pixel. However, the gate electrode and the source electrode of the TFT are partially overlapped, which results in the parasitic capacitor Cgs. When a turn-off voltage (Voff) is applied to the gate electrode to turn off the TFT, the Cgs will induce a voltage jump on the sub-pixel, and this voltage jump is called ΔVp, which can be calculated from the formula, ΔVp=[Cgs/(Clc+Cgs+Cst)]ΔVg, where Cgs is the capacitance of the parasitic capacitor, Clc is the capacitance of the liquid crystal capacitor, Cst is the capacitance of the storage capacitor, and ΔVg is the voltage difference between the Von and Voff of the gate line. When the source electrode shifts with respect to the gate electrode due to the instability in process conditions, the overlapping areas between the gate electrodes and source electrodes in the adjacent or nearby sub-pixels will be rendered not uniform, and the difference ΔVp′ will occur, and ΔVp′=ΔVp1−ΔVp2, where ΔVp1 and ΔVp2 are the above ΔVp values of the adjacent or nearby sub-pixels, respectively. If the ΔVp′ is not equal to 0, the gray scale of the adjacent or nearby sub-pixels will not be uniform, so that display quality degrades and the defective such as Mura can appear.

In the sub-pixel of the conventional TFT-LCD, when the gate voltage changes from Von to Voff, the capacitance of the parasitic capacitor Cgs between the gate electrode and the source electrode affects the gray scale of the pixel. When the process is stable, among the sub-pixels, the overlapping areas between the gate electrode and the source electrode are substantially identical, the magnitudes of the Cgs are substantially identical, the gray scales of the sub-pixels are substantially stable, thus a phenomenon that the gray scale of the sub-pixels are not uniform does not appear. However, when the instability in process condition induces the shift of the source electrode with respect to the gate electrode, the overlapping area between the source electrode and the gate electrode changes among sub-pixels, which results in Cgs different in magnitude, and the levels of gray scale in the adjacent or nearby sub-pixels are not uniform. In this case, the brightness in some regions is too high (white) while in some other regions is insufficient (black), thus the phenomenon of non-uniform gray scale of the image such as Mura appears.

FIG. 2 is a schematic view showing the thin film laminated structure on the conventional TFT-LCD array substrate, which is, for example, a partially cross-sectional view taken in a TFT device. As shown in FIG. 2, the thin films laminated on a substrate such as a glass substrate (not shown) comprise, from bottom to top, a gate metal layer thin film 1a, a gate insulating layer thin film 2a, an active layer thin film 3a, a source/drain metal layer thin film 4a, a passivation layer thin film 5a, and a pixel electrode thin film 6a, respectively, which are sequentially formed on a glass substrate during the manufacturing of the array substrate.

FIG. 3A is a top view showing the sub-pixel structure of a conventional TFT-LCD array substrate; FIG. 4A is an enlarged view showing the TFT device in FIG. 3A; and FIG. 4B is a cross-sectional view taken along the line A-A in FIG. 4A.

As shown in FIGS. 3A, 4A, and 4B, on the glass substrate (not shown), there are formed a plurality of gate lines 21 extending in the horizontal direction, and a plurality of data lines 4 extending in the vertical direction, and these gate lines and data lines cross with each other to define a plurality of sub-pixels. Thus, the sub-pixel substantially comprises: a gate line 21 and a gate electrode 1 formed on the substrate; a gate insulating layer 2 formed on the gate line 21 and the gate electrode 1; an active layer 3 formed on the gate insulating layer 2; a data line 4, a drain electrode 7 and a source electrode 8 formed on the active layer 3; a passivation layer 5 covering the data line 4, the drain electrode 7 and the source electrode 8; and a pixel electrode 6 formed on the passivation layer 5, wherein the passivation layer 5 correspondingly forms a passivation layer via hole 11 over the source electrode 8, the pixel electrode 6 is connected to the source electrode 8 through the via hole 11, and the overlapping region 12 between the pixel electrode 6 and the gate electrode 1 constitutes the storage capacitor Cst.

The structure shown in FIG. 3B is obtained by adding gate metal layer light blocking strips 13 to the structure shown in FIG. 3A, and the light blocking strips are arranged on both sides of the pixel electrode and partially overlap with the pixel electrode so as to prevent leakage of light to improve the contrast. The structure shown in FIG. 3C is obtained by further adding a gate metal layer common electrode 14 to the structure shown in FIG. 3B, which traverses the sub-pixel under the pixel electrode to increase the storage capacitor. Among the three kinds of sub-pixel structure as shown in FIGS. 3A-3C, the construction of the TFT acting as the switching element is similar, as shown in FIG. 4A.

As shown in FIG. 4A, the overlapping region 109 between the gate electrode 1 and the source electrode 8 in the TFT is in a rectangular shape. If the overlapping region 9 of the gate electrode 1 and the source electrode 8 in an array substrate has a length L of 6 μm and a width W of 30 μm, the overlapping region 9 between the gate electrode 1 and the source electrode 8 has an area of A=L×W=6×30=180 μm² when the process conditions are stable. However, when the process conditions are unstable, which is generally inevitable during the manufacturing, there are two cases in which the source electrode 8 will shift with respect to the gate electrode 1. In the first case, the source electrode 8 shifts with respect to the gate electrode 1 along the vertical direction in the figure, while in the second case, the source electrode 8 shifts with respect to the gate electrode 1 along the horizontal direction the figure. In the first case, the shift will have no influence on the area of the overlapping region, while in the second case, the shift will change the area of the overlapping region. Hereinafter, the discussion focuses on the second case, i.e., the source electrode 8 shifts with respect to the gate electrode 1 along the horizontal direction. Provided that the gate electrode 1 shifts 1 μm to the left with respect to the gate electrode 1 in the horizontal direction, the length L of the overlapping region 9 between the source electrode 8 and the gate electrode 1 changes to 7 μm while the width W is unchanged, thus the area of the overlapping region 9 between the source electrode 8 and the gate electrode 1 is changed to S_{shift}=7×30=210 μm². Meanwhile, in the case that the dielectric constant and the distance between these two electrodes are kept constant, the change ratio of the parasitic capacitor Cgs is: (210−180)/180=16.7%. According to the following formula,

$$Δ Vp = \frac{Cgs}{Cgs + Clc + Cst} ( Von - Voff ) ,$$

in case that other parameters are kept constant, the change in the parasitic capacitor Cgs will induce a change ratio over 16.7% for the difference ΔVp of the adjacent or nearby sub-pixels. The change in ΔVp will in turn induce the difference in the voltage of the adjacent or nearby sub-pixels and cause Mura.

### SUMMARY OF THE INVENTION

In view of the above problems, according to an aspect of the present invention, there is provided a TFT-LCD array substrate with a self-compensating parasitic capacitor structure and the manufacturing method thereof. When the process conditions are unstable and the overlapping area of the parasitic capacitor changes, a self-compensating function can be realized by the change of the compensating parasitic capacitor, so that the total capacitance of the parasitic capacitor Cgs of each sub-pixel is kept constant, the shift of ΔVp among the sub-pixels is uniform, and the influence of the phenomena of flicker and Mura on the image quality will decrease.

According to one aspect of the invention, there is provided a TFT-LCD array substrate. The TFT-LCD array substrate comprises a substrate, and at least one gate line and at least one data line are formed on the substrate and cross with each other to define sub-pixel regions. One of the sub-pixel regions includes a thin film transistor (TFT) and a pixel electrode, and the TFT is electrically connected to the pixel electrode. The TFT-LCD array substrate further comprises a compensating parasitic capacitor structure comprising a first electrode electrically connected to the gate line and a second electrode electrically connected to the pixel electrode.

Preferably, the TFT is a bottom-gate type TFT, wherein the source electrode is electrically connected to the pixel electrode through a first via hole formed in a passivation layer.

Preferably, the compensating parasitic capacitor structure comprises: a compensating gate electrode serving as the first electrode, which is electrically connected to the gate line; the gate insulating layer and a compensating active layer that serve as dielectric layers, which are formed sequentially on the compensating gate electrode; and a compensating source electrode serving as the second electrode, which is formed on the compensating active layer; and wherein the passivation layer is formed on the compensating source electrode, and the compensating source electrode is electrically connected to the pixel electrode through a second via hole formed in the passivation layer.

Preferably, an overlapping region between the gate electrode and the source electrode and an overlapping region between the compensating gate electrode and the compensating source electrode are parallel with each other and have the same width in the parallel direction.

Preferably, the compensating active layer is integrated with the active layer of the TFT, the compensating source electrode is integrated with the source electrode of the TFT, and the second via hole through which the compensating source electrode and the pixel electrode are connected with each other is the same one as the first via hole through which the source electrode of the TFT and the pixel electrode are connected with each other.

Alternatively, the compensating active layer is separated from the active layer of the TFT, the compensating source electrode is separated from the source electrode of the TFT, and the second via hole through which the compensating source electrode and the pixel electrode are connected with each other is different from the first via hole through which the source electrode of the TFT and the pixel electrode are connected with each other.

According to another aspect of the invention, there is provided a method of manufacturing a TFT-LCD array substrate. The method comprises the following steps. A gate metal thin film is deposited on a substrate and is patterned to form at least one gate line, and a gate electrode of a TFT and a compensating gate electrode are formed with the gate line. A gate insulating layer thin film and an active layer thin film are sequentially deposited on the substrate, and the active layer thin film is patterned to form an active layer and a compensating active layer on the gate electrode and the compensating gate electrode, respectively. A source/drain metal thin film is deposited on the substrate and is patterned to form a data line, a drain electrode, a source electrode, and a compensating source electrode, in which the drain electrode and the source electrode are separated from each other with respect to the gate electrode and formed on the active layer, the drain electrode is connected to the data line, and the compensating source electrode is formed over the compensating gate electrode through the gate insulating thin film and the compensating gate electrode. A passivation layer thin film is deposited on the substrate and is patterned to form at least one via hole over the source electrode and the compensating source electrode. A pixel electrode thin film is deposited on the substrate and is patterned to form a pixel electrode, in which the pixel electrode is connected to the source electrode and the compensating source electrode through the at least one via hole.

Preferably, an overlapping region between the gate electrode and the source electrode and an overlapping region between the compensating gate electrode and the compensating source electrode are parallel with each other and have the same width in the parallel direction.

As compared with the conventional array substrate, by providing a self-compensating capacitor structure comprising the compensating parasitic capacitor Cgs2 in the present invention, when the process conditions are unstable and the shift of the source electrode with respect to the gate electrode is induced, the normal parasitic capacitor Cgs1 and the compensating parasitic capacitor Cgs2 can compensate with each other, so that the total capacitance of the parasitic capacitor Cgs of the sub-pixel structure can remain constant. Therefore, the performance degradation due to the non-uniform parasitic capacitor Cgs among the sub-pixels can be suppressed, the image quality of the product can be improved, and the yield of the product can be increased.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the following detailed description.

### BRIEF DESCRIPTION OF THE DRAWINGS

The present invention will become more fully understood from the detailed description given hereinafter and the accompanying drawings which are given by way of illustration only, and thus are not limitative of the present invention and wherein:

FIG. 1 is a circuit diagram of a single sub-pixel of the conventional TFT-LCD array substrate;

FIG. 2 is a view showing the thin film laminated structure on the conventional TFT-LCD array substrate;

FIG. 3A is a top view showing the sub-pixel structure of a conventional TFT-LCD array substrate;

FIG. 3B is a top view showing the sub-pixel structure of a conventional TFT-LCD array substrate with light blocking strips;

FIG. 3C is a top view showing the sub-pixel structure of a conventional TFT-LCD array substrate with light blocking strips and a common electrode line;

FIG. 4A is an enlarged view showing the TFT device in FIG. 3A;

FIG. 4B is a cross-sectional view taken along the line A-A in FIG. 4A;

FIG. 5A is a schematic view showing the sub-pixel of the TFT-LCD array substrate with a self-compensating parasitic capacitor structure according to the first embodiment of the present invention;

FIG. 5B is an enlarged view showing the TFT device in FIG. 5A;

FIG. 5C is a cross-sectional view taken along the line B-B in FIG. 5B;

FIG. 6A is a schematic view showing the sub-pixel of the TFT-LCD array substrate with a self-compensating parasitic capacitor structure according to the second embodiment of the present invention;

FIG. 6B is an enlarged view showing the TFT device in FIG. 6A;

FIG. 7A is a schematic view showing the sub-pixel structure of the TFT-LCD array substrate with a self-compensating parasitic capacitor structure according to the third embodiment of the present invention;

FIG. 7B is an enlarged view showing the TFT device in FIG. 7A;

FIG. 7C is a cross-sectional view taken along the line C-C in FIG. 7B;

FIG. 8A is a schematic view showing the sub-pixel structure of the TFT-LCD array substrate with a self-compensating parasitic capacitor structure according to the fourth embodiment of the present invention;

FIG. 8B is all enlarged view showing the TFT device in FIG. 8A;

FIG. 9A is a schematic view showing the sub-pixel structure of the TFT-LCD array substrate with a self-compensating parasitic capacitor structure according to the fifth embodiment of the present invention;

FIG. 9B is an enlarged view showing the TFT device in FIG. 9A;

FIG. 9C is a cross-sectional view taken along the line D-D in FIG. 9B;

FIG. 10A is a schematic view showing the sub-pixel structure of the TFT-LCD array substrate with a self-compensating parasitic capacitor structure according to the sixth embodiment of the present invention;

FIG. 10B is an enlarged view showing the TFT device in FIG. 10A;

FIG. 11A is a schematic view showing the sub-pixel structure of the TFT-LCD array substrate with a self-compensating parasitic capacitor structure according to the seventh embodiment of the present invention;

FIG. 11B is an enlarged view showing the TFT device in FIG. 11A;

FIG. 11C is a cross-sectional view taken along the line E-E in FIG. 11B;

FIG. 12A is a schematic view showing the sub-pixel structure of the TFT-LCD array substrate with a self-compensating parasitic capacitor structure according to the eighth embodiment of the present invention;

FIG. 12B is an enlarged view showing the TFT device in FIG. 12A;

FIG. 13 is a circuit diagram showing a single sub-pixel of the TFT-LCD array substrate with double parasitic capacitors in the self-compensating structure according to the present invention of the present invention;

FIG. 14 is a top view showing the TFT-LCD array substrate after completing the process of the gate metal layer;

FIG. 15 is a top view showing the TFT-LCD array substrate after completing the process of the active layer; and

FIG. 16 is a top view showing the TFT-LCD array substrate after completing the process of the source/drain metal layer.

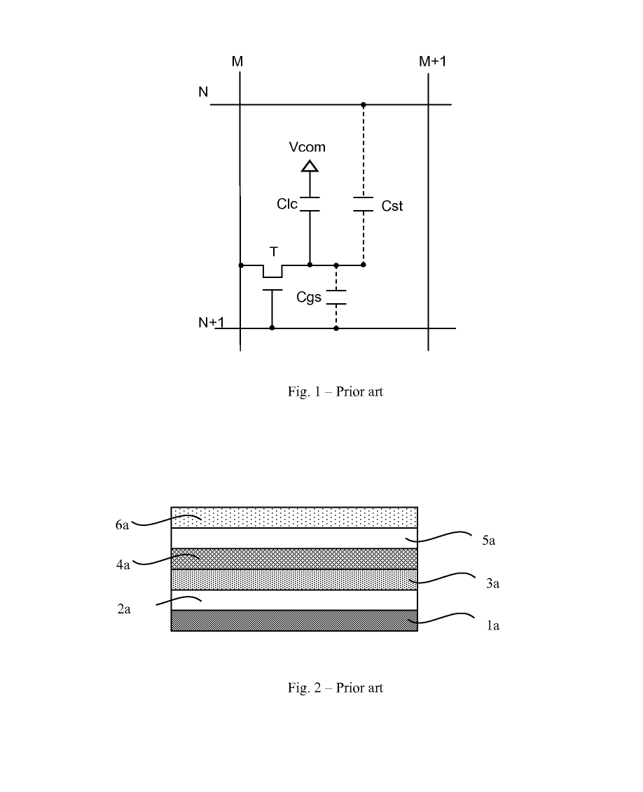

### DETAILED DESCRIPTION OF THE PREFERRED EMBODIMENTS

The exemplary embodiments according to the present invention will be described hereinafter in detail with reference to the accompanying drawings. This invention may, however, be embodied in many different forms and should not be construed as limited to the embodiments set forth herein. In the context, it will be understood that when an element or layer is referred to as being “on” or “connected to” another element or layer, it can be directly on or connected to the other element or layer or intervening elements or layers may be present. Throughout this disclosure, the same reference number indicates the same or similar layer or element among the embodiments.

### The First Embodiment

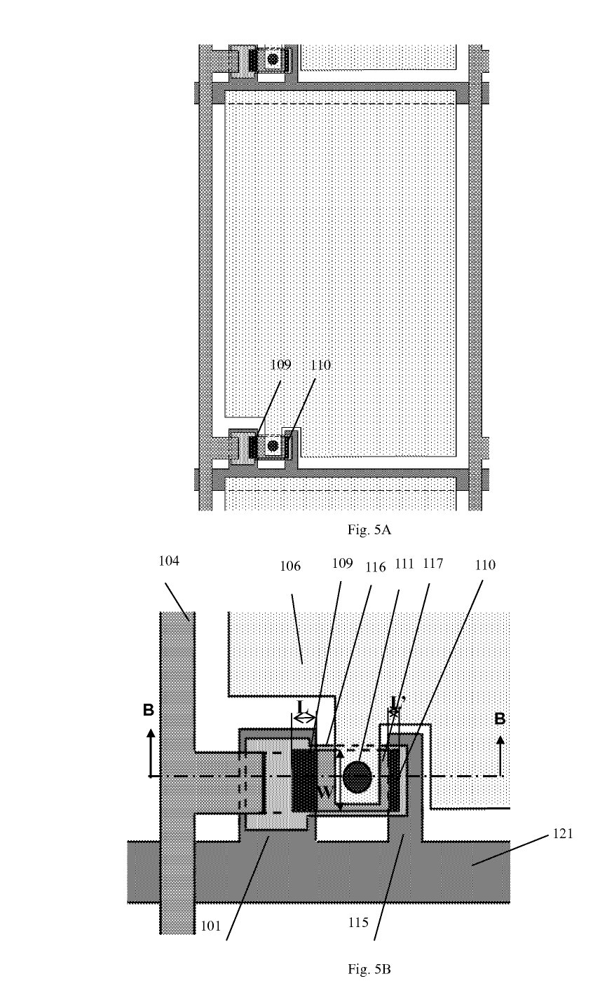

FIG. 5A is a schematic view showing the sub-pixel structure of the TFT-LCD array substrate with a self-compensating parasitic capacitor structure according to the first embodiment of the present invention. As shown in FIG. 5A, in addition to an overlapping region 109 of a gate electrode 101 and a source electrode 108 which form the normal parasitic capacitor Cgs1, an overlapping region 110 between a compensating source electrode 115 and the compensating gate electrode 117 is produced to form a compensating parasitic capacitor Cgs2, i.e., the self-compensating parasitic capacitor structure of the first embodiment. In the first embodiment, the parasitic capacitor Cgs1 and the compensating parasitic capacitor Cgs2 are formed at the positions of the TFT in the horizontal direction, as shown in FIG. 5A. The parasitic capacitor Cgs1 and the compensating parasitic capacitor Cgs2 are connected in parallel with each other, and the sum of these capacitors constitutes the total parasitic capacitor Cgs between the pixel electrode and the gate line.

FIG. 5B is an enlarged view showing the TFT device in FIG. 5A, and FIG. 5C is a cross-sectional view taken along the line B-B in FIG. 5B. As shown in FIGS. 5A and 5B, the TFT-LCD array substrate according to the first embodiment comprises: a plurality of gate lines 121, which are parallel with each other and extend in the horizontal direction, and a plurality of data lines 104, which are parallel with each other and extend in the vertical direction, and the adjacent gate lines 121 and data lines 104 cross with each other and define an array of sub-pixels. Each sub-pixel comprises: the gate electrode 101 protruding from a gate line 121 formed on a substrate such as a glass or plastic substrate, a gate insulating layer 102, an active layer 103, the data line 104, a drain electrode 107, a source electrode 108, a passivation layer 105, a via hole 111, and a pixel electrode 106, wherein the gate electrode 101, the gate insulating layer 102, the active layer 103, the data line 104, the drain electrode 107, and the source electrode 108 form a TFT device. The gate electrode 101 and the source electrode 108 overlap with each other to form the overlapping region 109 and serve as two plates of the parasitic capacitor Cgs1 in the overlapping region 109, with the gate insulating layer 102 and the active layer 103 therebetween as a dielectric layer, as shown in FIG. 5C by the left circled portion corresponding to the overlapping region 109. The structure and the connection relationship among the above-described components are similar to those of the sub-pixels in the conventional TFT LCD array, which are not repeated herein for simplicity.

The sub-pixel according to the first embodiment further comprises the compensating gate electrode 115, a compensating active layer 116 formed on the compensating gate electrode 115, and the compensating source electrode 117 formed on the compensating active layer 116. The compensating gate electrode 115 and the compensating source electrode 117 overlap with each other to form the overlapping region 110 and serve as two plates of the compensating parasitic capacitor Cgs2 in the overlapping region 110, with the gate insulating layer 102 and the compensating active layer 116 therebetween as a dielectric layer, as shown in FIG. 5C by the right circled portion corresponding to the overlapping region 110.

Moreover, in the first embodiment, the gate electrode 101 and the compensating gate electrode 115 are separated from each other by a certain distance in the extending direction of the gate line, and as shown in FIG. 5B, the overlapping regions 109, 110 are parallel with each other and have the same width in the parallel direction, i.e., in the vertical direction in FIG. 5B. The active layer 103 is integrated with the compensating active layer 116, and the source electrode 108 is integrated with the compensating source electrode 117. Because the source electrode 108 is integrated with the compensating source electrode 117, there can be only one via hole 111 in the passivation layer 105, through which the source electrode 108 and the compensating source electrode 117 can be connected to the pixel electrode 106.

Hereinafter, the self-compensating mechanism in the first embodiment is described with reference to FIG. 5B. In the first embodiment, in addition to the normal parasitic capacitor Cgs1 formed by the overlapping region 109 between the source electrode 108 and the gate electrode 101, there is further provided a compensating parasitic capacitor structure, which uses the compensating gate electrode 115 and the compensating source electrode 117 in the overlapping region 110 as two plates and the gate insulating layer 102 and the compensating source layer 116 as the dielectric layer to form the compensating parasitic capacitor structure and thus forming the compensating parasitic capacitor Cgs2, that is, the self-compensating parasitic capacitor structure. In the presence of the compensating parasitic capacitor Cgs2, it is assumed that the length L of the overlapping region 109 between the gate electrode 101 and the source electrode 108 is equal to 6 μm and the width W is equal to 30 μm, while the length L′ of the overlapping region 110 between the compensating gate electrode 115 and the compensating source electrode 117 is equal to 3 μm and the width W is still equal to 30 μm as that of the region 109. When the process conditions are stable, the area of the overlapping region 109 is A=6×30=180 μm², the area of the overlapping region 110 is B=3×30=90 μm², and the total area of these overlapping regions is A+B=180+90=270 μm², which will brings no problem to the stability of Cgs and the display quality. When the process conditions are not stable, as shown in FIG. 5A, the shift of source electrode 108 with respect to the gate electrode 101 in the vertical direction will not influence the area of the overlapping regions. Therefore only the case in which the source electrode 108 shifts with respect to the gate electrode 101 in the horizontal direction will be described in detail as below. It is still assumed that the source electrode 108 shifts by 1 μm to the left with respect to the gate electrode 101 in the horizontal direction. Since the overlapping regions 109, 110 are parallel with each other and have the same width in the parallel direction, when the source electrode 108 shifts by 1 μm to the left with respect to the gate electrode 101 in the horizontal direction, the compensating source electrode 117 will also shifts by 1 μm to the left with respect to the compensating gate electrode 115 in the horizontal direction. Then, the length L of the overlapping region 109 between the gate electrode 101 and the source electrode 108 is changed to 7 μm and the width W remains unchanged, thus the area of the overlapping region 109 is changed to A′=7×30=210 μm², while the length L′ of the overlapping region 110 between the compensating gate electrode 115 and the compensating source electrode 117 is changed to 2 μm and the width W remains unchanged, and thus the area of the overlapping region 110 is changed to B′=2×30=60 μm². The total area of the overlapping regions 109 and 110 is 210+60=270 μm², which equals to the total area of 270 μm² when the process conditions are stable, so that the total parasitic capacitor Cgs remains unchanged, and the problem of variations in the parasitic capacitor due to the unstable process conditions can be prevented effectively. Similarly, when the source electrode 108 shifts to the right with respect to the gate electrode 101, the decreased area of the overlapping region 109 is equal to the increased area of the overlapping region 110, so that the total area of the overlapping region 109 and 110 are kept unchanged, i.e., the total capacitance of the parasitic capacitor Cgs is kept constant. According to the following formula,

$$Δ Vp = \frac{Cgs}{Cgs + Clc + Cst} ( Von - Voff )$$

assuming other parameters are kept constant, since the parasitic capacitor Cgs remains constant, ΔVp will be uniform and the gray scale of the sub-pixels will be uniform among adjacent or nearby sub-pixels, so that the image quality will be improved, the occurrence of Mura due to the non-uniform image display will be greatly suppressed, and also the yield of the product will be increased.

### The Second Embodiment

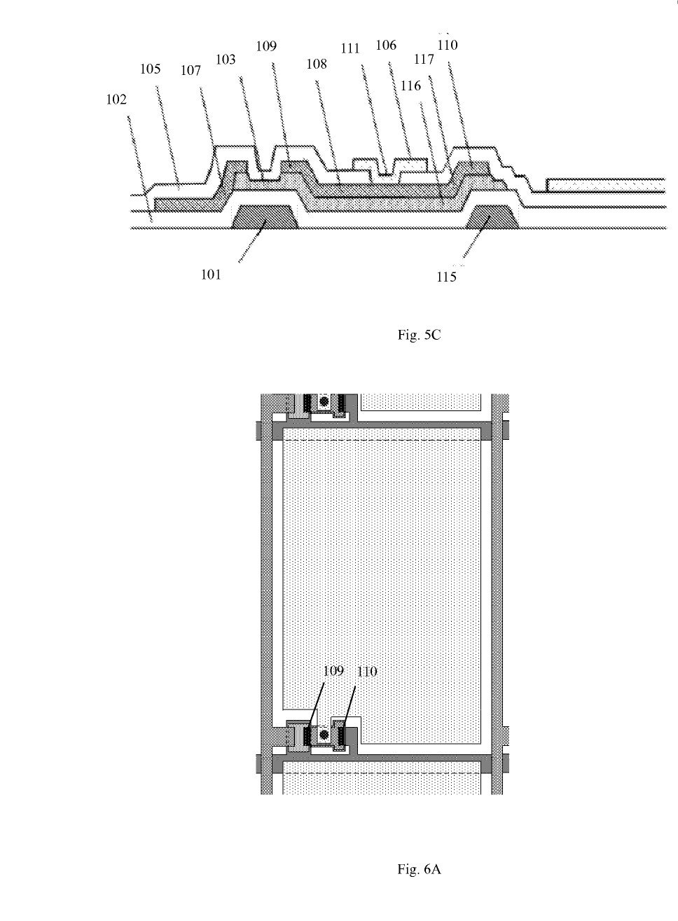

FIG. 6A is a schematic view showing the sub-pixel structure of the TFT-LCD array substrate with a self-compensating parasitic capacitor structure according to the second embodiment of the present invention. FIG. 6B is an enlarged view showing the TFT device in FIG. 6A.

As shown in FIGS. 6A and 6B, the sub-pixel structure of the second embodiment is substantially similar to that in the first embodiment, and the difference lies in the overlapping structure realizing the compensating parasitic capacitor. In both the first and second embodiments, the compensating parasitic capacitor Cgs2 is realized by superposing the compensating source electrode 117 over the compensating gate electrode 115. However, in the compensating parasitic capacitor in the first embodiment, the compensating gate electrode 115 in the overlapping region 110 has a larger width, so that the width of the overlapping region 110 is determined by the width of the compensating source electrode 117, while in the second embodiment, the compensating source electrode 117 in the overlapping region 110 has a larger width, so that the width of the overlapping region 110 is determined by the width of the compensating gate electrode 115. Furthermore, in the second embodiment, the width of the compensating gate electrode 115 in the overlapping region 110 is equal to that of the source electrode 108, so that the overlapping regions 109 and 110 have the same width in the parallel direction. Thus, when the source electrode shifts with respect to the gate electrode in the horizontal direction, the decreased or increased capacitance of the parasitic capacitor Cgs1 is equal to the increased or decreased capacitance of the compensating parasitic capacitor Cgs2, so that the total capacitance of the parasitic capacitor Cgs is unchanged.

### The Third Embodiment

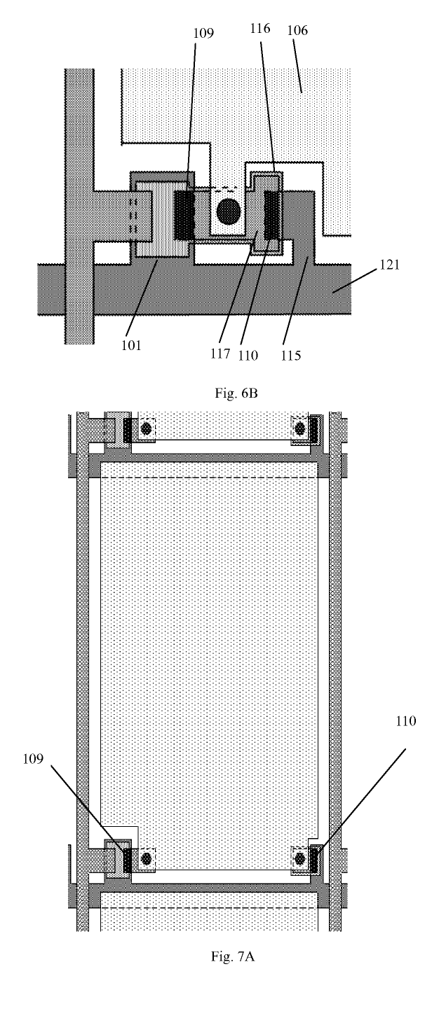

FIG. 7A is a schematic view showing the sub-pixel structure of the TFT-LCD array substrate with a self-compensating parasitic capacitor structure according to the third embodiment of the present invention; FIG. 7B is an enlarged view showing the TFT device in FIG. 7A; and FIG. 7C is a cross-sectional view taken along the line C-C in FIG. 7B.

As shown in FIGS. 7A˜7C, the TFT and the compensating parasitic capacitor Cgs2 according to the third embodiment are disposed on two sides of the pixel electrode near the data lines, respectively. The TFT in the third embodiment is the same as that in the first embodiment, the parasitic capacitor structure is similar to that in the first embodiment, and the difference lies in that: in the third embodiment, the gate electrode 101 and the compensating gate electrode 115 are separated apart far away from each other in the extending direction of the gate line, the active layer 103 and the compensating active layer 116 formed over the gate insulating layer 102 are separated apart, and the source electrode 108 and the compensating source electrode 117 formed over the active layer are also separated apart. Since the source electrode 108 and the compensating source electrode 117 need be connected to the pixel electrode 106 simultaneously to realize the self-compensating function, via holes (two in the case of the present embodiment) need be formed in the passivation layer 105 over the source electrode 108 and the compensating source electrode 117, respectively, in order to connect the source electrode 108 and the compensating source electrode 117 to the pixel electrode 106, respectively. The overlapping region 109 formed by the gate electrode 101 and the source electrode 108 and the overlapping region 110 formed by the compensating gate electrode 115 and the compensating source electrode 117 are parallel with each other and have the same width in the parallel direction. The self-compensating mechanism in the third embodiment is the same as that in the first embodiment, and therefore is not repeated herein for simplicity.

### The Fourth Embodiment

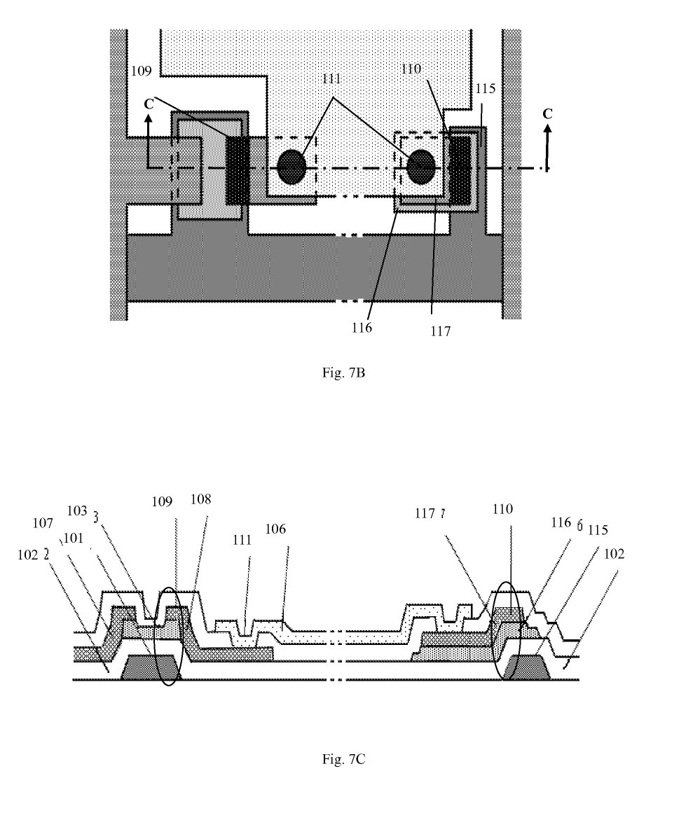

FIG. 8A is a schematic view showing the sub-pixel structure of the TFT-LCD array substrate with a self-compensating parasitic capacitor structure according to the fourth embodiment of the present invention; and FIG. 8B is an enlarged view showing the TFT device in FIG. 8A.

As shown in FIGS. 8A and 8B, the sub-pixel structure of the fourth embodiment is substantially similar to that shown in the third embodiment, and the difference lies in the structure of the overlapping region 110. In the third embodiment, the compensating parasitic capacitor Cgs2 is formed by superposing the compensating source electrode 117 over the compensating gate electrode 115, and the width of the overlapping region 110 is determined by the width of the compensating source electrode 117, while in the fourth embodiment, the width of the overlapping region 110 is determined by the width of the compensating gate electrode 115, and the width of the compensating gate electrode is equal to that of the source electrode 108. The self-compensating mechanism in the fourth embodiment is the same as that in the third embodiment, and is not described herein for simplicity.

### The Fifth Embodiment

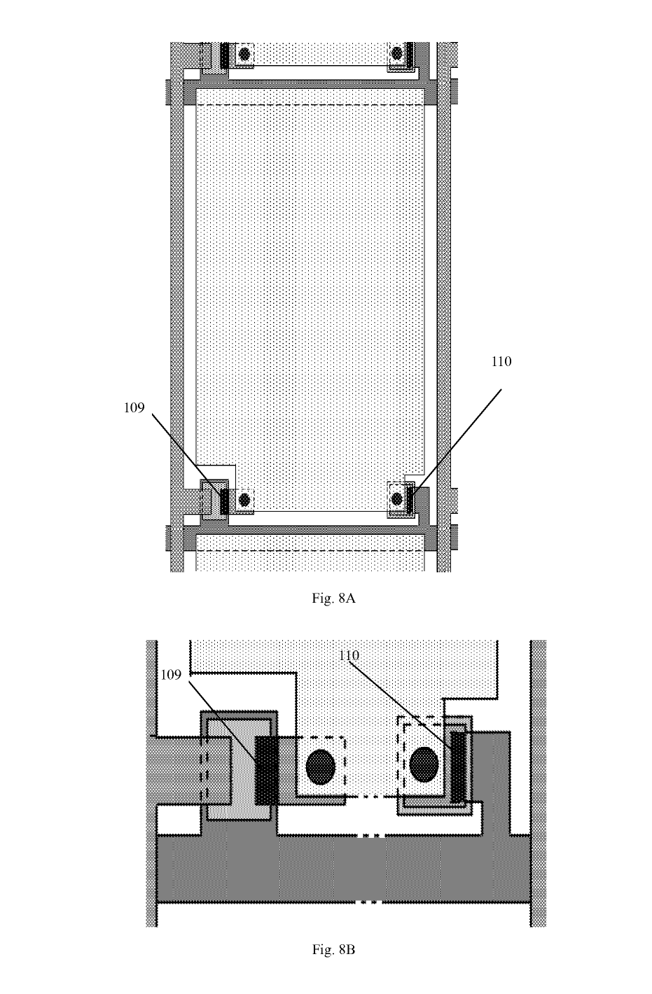

FIG. 9A is a schematic view showing the sub-pixel structure of the TFT-LCD array substrate with a self-compensating parasitic capacitor structure according to the fifth embodiment of the present invention; FIG. 9B is an enlarged view showing the TFT device in FIG. 9A; and FIG. 9C is a cross-sectional view taken along the line D-D in FIG. 9B.

As shown in FIGS. 9A˜9C, the TFT and the compensating parasitic capacitor Cgs2 according to the fifth embodiment are similar to those in the first embodiment, and the difference lies in that: in the fifth embodiment, the TFT and the compensating parasitic capacitor Cgs2 are disposed in a direction perpendicular to the gate line 121, and the TFT is partially formed on the gate line, i.e., a portion of the gate line serves as the gate electrode of the TFT. The active layer 103 is formed on and extends perpendicularly to the gate line 121, and the source electrode 108 and drain electrode 107 are formed on both ends of the overlapping region between the gate line 121 and the active layer 102 respectively. The overlapping region 109 is formed between the source electrode 108 and the portion of the gate line that serves as the gate electrode. Similar to the first embodiment, the compensating source electrode 117 is integrated with the source electrode 108, and the active layer 103 is integrated with the compensating active layer 106. The compensating gate electrode 115 is formed of a branch of the gate line 121. The compensating gate electrode 115 is parallel with the direction of the gate line, and forms the overlapping region 110 with the compensating source electrode 117. The overlapping regions 109 and 110 are parallel with each other and have the same width in the parallel direction, i.e., in the horizontal direction in FIG. 9B

The self-compensating mechanism in the fifth embodiment is similar to that in the first embodiment. In the fifth embodiment, when the process conditions are unstable, the shift of the source electrode 108 with respect to the gate electrode in the horizontal direction will not influence the total area of the overlapping regions 109 and 110, and the case in which the shift in the vertical direction will be only described in detail as below. When the source electrode 108 shifts upward with respect to the gate electrode in the vertical direction, the width of the overlapping regions 109 and 110 remain unchanged, and the increased or decreased length of the overlapping region 109 is equal to the decreased or increased length of the overlapping region 110, so that the total area of the overlapping regions 109 and 110 remains constant, i.e., the total capacitance of the parasitic capacitor Cgs is kept constant.

### The Sixth Embodiment

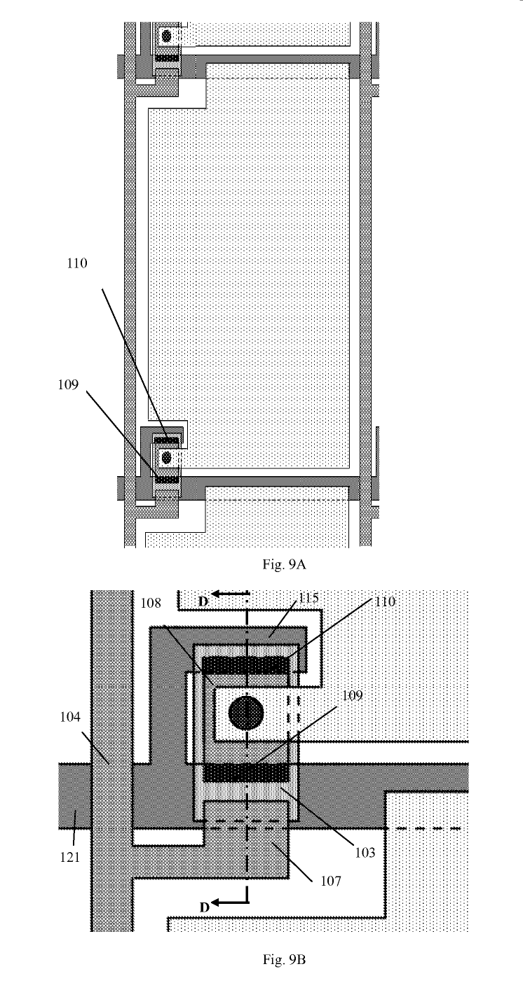

FIG. 10A is a schematic view showing the sub-pixel structure of the TFT-LCD array substrate with a self-compensating parasitic capacitor structure according to the sixth embodiment of the present invention; and FIG. 10B is an enlarged view showing the TFT device in FIG. 10A.

As shown in FIGS. 10A and 10B, the sub-pixel structure of the sixth embodiment is substantially similar to that in the fifth embodiment, and the difference lies in the structure of the overlapping region 110. In the fifth embodiment, the compensating parasitic capacitor Cgs2 is formed by superposing the compensating source electrode 117 over the compensating gate electrode 115, and the width of the overlapping region 110 is determined by the width of the compensating source electrode 117, while in the sixth embodiment, the width of the overlapping region 110 is determined by the width of the compensating gate electrode 115. The self-compensating mechanism in the sixth embodiment is the same as that in the fifth embodiment and is not repeated herein for simplicity.

### The Seventh Embodiment

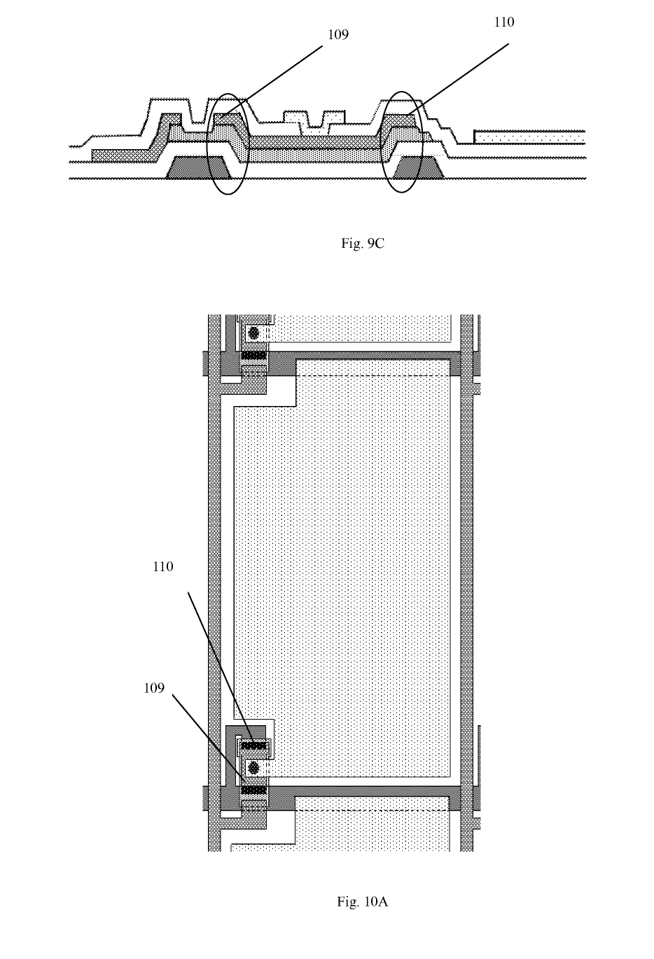

FIG. 11A is a schematic view showing the sub-pixel structure of the TFT-LCD array substrate with a self-compensating parasitic capacitor structure according to the seventh embodiment of the present invention; FIG. 11B is an enlarged view showing the TFT device in FIG. 11A; and FIG. 11C is a cross-sectional view taken along the line E-E in FIG. 11B.

As shown in FIGS. 11A to 11C, the TFT according to the seventh embodiment is similar to that in the sixth embodiment, which is formed on the gate line in a direction perpendicular to the gate line, and a portion of the gate line serves as the gate electrode of the TFT. In addition, the compensating parasitic capacitor Cgs2 in the seventh embodiment is formed on a position on the gate line far away from the TFT, i.e., the compensating gate electrode 115 and the portion of the gate line serving as the gate electrode of TFT are separated apart far away from each other. Therefore, the active layer 103 and the compensating active layer 116 formed over the gate insulating layer 102 are separated apart, and the source electrode 108 and the compensating source electrode 117 formed over the active layer are also separated apart. Since the source electrode 108 and the compensating source electrode 117 need be connected to the pixel electrode 106 simultaneously to realize the self-compensating function, via holes (e.g. two as shown) need be formed in the passivation layer 105 over the source electrode 108 and the compensating source electrode 117, respectively, in order to connect the source electrode 108 and the compensating source electrode 117 to the pixel electrode 106, respectively. The overlapping region 109 formed by the gate electrode and the source electrode and the overlapping region 110 formed by the compensating gate electrode and the compensating source electrode are parallel with each other and have the same width in the parallel direction. Besides, the source electrode 108 and the compensating source electrode 117 have the same width to realize the self-compensating mechanism according to the seventh embodiment. The self-compensating mechanism in the seventh embodiment is the same as that in the fifth embodiment.

### The Eighth Embodiment

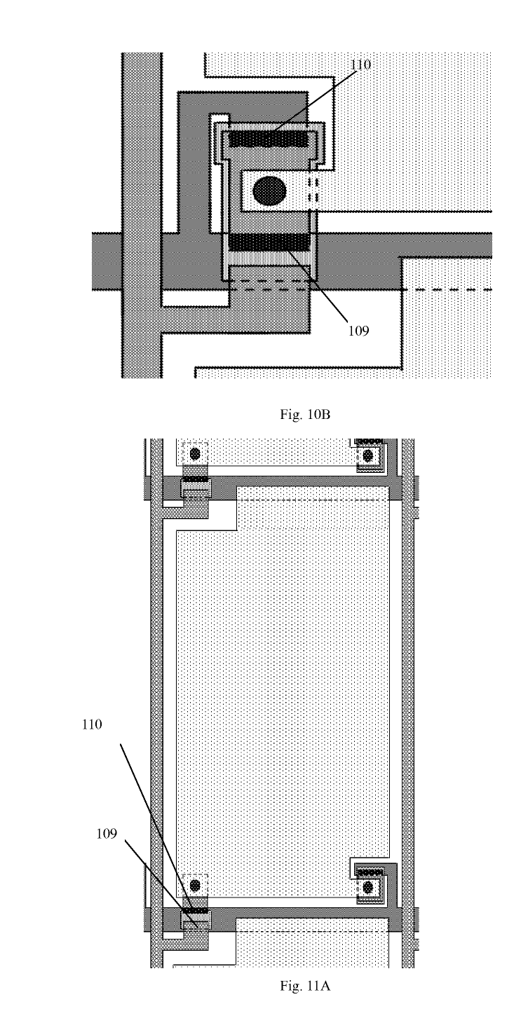

FIG. 12A is a schematic view showing the sub-pixel structure of the TFT-LCD array substrate with a self-compensating parasitic capacitor structure according to the eighth embodiment of the present invention, and FIG. 12B is an enlarged view showing the TFT device in FIG. 12A.

As shown in FIGS. 12A and 12B, the sub-pixel structure of the eighth embodiment is substantially similar to that in the seventh embodiment, and the difference lies in the overlapping structure for forming the parasitic capacitor. In the seventh embodiment, the compensating parasitic capacitor Cgs2 is formed by superposing the compensating source electrode 117 over the compensating gate electrode 115, and the width of the overlapping region 110 is determined by the width of the compensating source electrode 117, while in the eighth embodiment, the width of the overlapping region 110 is determined by the width of the compensating gate electrode 115. The self-compensating mechanism in the eighth embodiment is the same as that in the fifth embodiment.

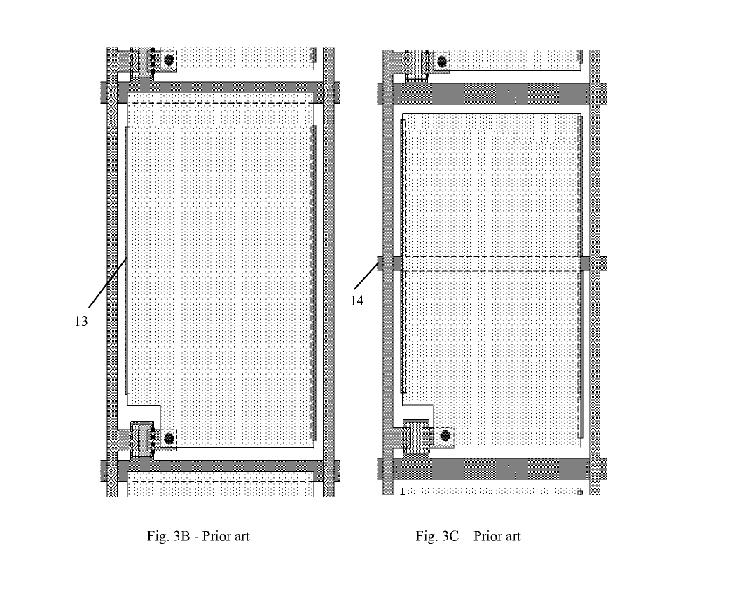

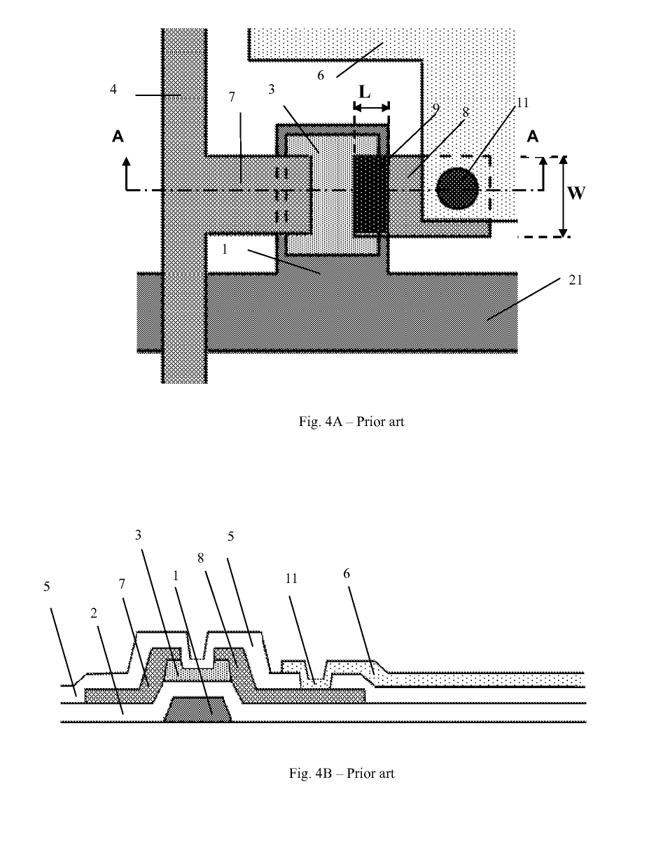

Similar to the TFT-LCD array substrate shown in FIGS. 3B and 3C, the additional structure such as the gate metal layer light blocking strip and/or the gate metal layer common electrode can be provided in the sub-pixel structure according to the first to eighth embodiments of the present invention as necessary.

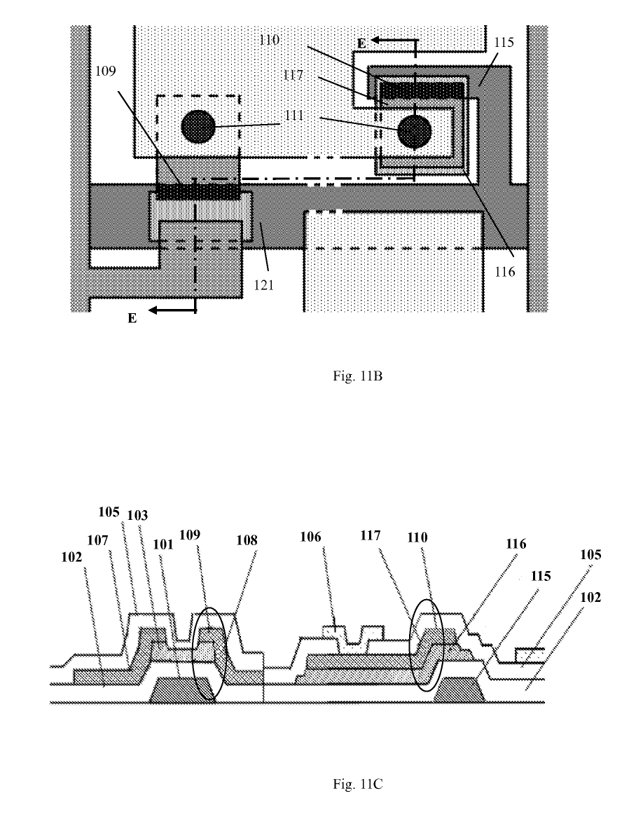

The sub-pixel structures in the first to eighth embodiments of the present invention are exemplary structures and include eight types of structures in total, and the circuit diagram of a single sub-pixel structure for the TFT-LCD array substrate with one of self-compensating parasitic capacitor structures is shown in FIG. 13. In FIG. 13, N represents the n^{th} gate line, (N+1) represents the (n+1)^{th} gate line; while M represents the m^{th} data line, (M+1) represents the (m+1)^{th} data line. T represents the TFT serving as a switching element, in which the gate electrode is connected to the (n+1)^{th} gate line, the drain electrode is connected to the m^{th} data line, and the source electrode is connected to the pixel electrode. The circuit diagram shown in FIG. 13 also includes the parasitic capacitor Cgs1, the compensating capacitor Cgs2, the capacitor of the liquid crystal Clc, and the storage capacitor Cst. The parasitic capacitor Cgs1 and the compensating parasitic capacitor Cgs2 are connected in parallel with each other, and the sum of these capacitors is referred as the total parasitic capacitor Cgs. It is noted that the source electrode of the TFT is electrically connected to the pixel electrode in the above description, it should be appreciated by those skilled in the art that the source electrode and the drain electrode can be exchanged in the TFT, namely, the source electrode can be electrically connected to the data line while the drain electrode is electrically connected to the pixel electrode. Further, the source electrode and the drain electrode can be generally called the source/drain electrode.

The design of providing self-compensating parasitic capacitor to prevent the jittering of variation of the parasitic capacitor Cgs during the unstable process can assume a sub-pixel structure in other shapes and patterns, and these shapes and patterns all fall into the spirit and scope of the present invention.

The TFT-LCD array substrate having the above-described sub-pixel structure can be manufactured by the following method of the present invention. In the following description, the manufacturing of the sub-pixel structure of the TFT-LCD array substrate according to the first embodiment will be explained as an example, but the manufacturing methods for the second to eighth embodiments are similar, and their difference only lies in the change of positional relationship between the gate electrode and the compensating gate electrode, between the active layer and the compensating active layer, and between the source electrode and the compensating source electrode.

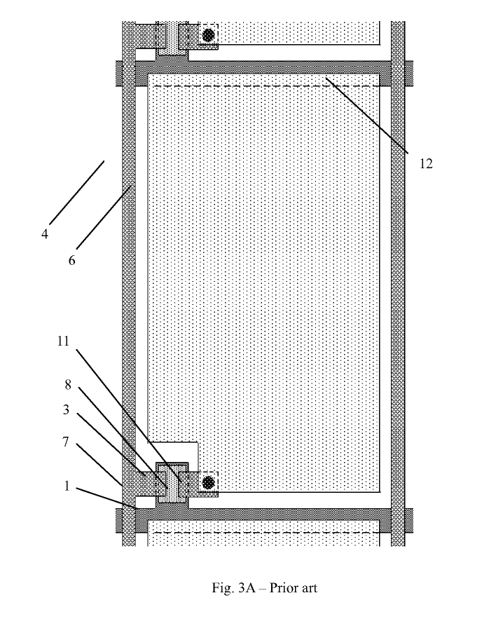

The schematic view for the thin films laminated on the TFT-LCD array substrate according to the embodiment of the present invention is the same as that shown in FIG. 2 and is not repeated herein for simplicity.

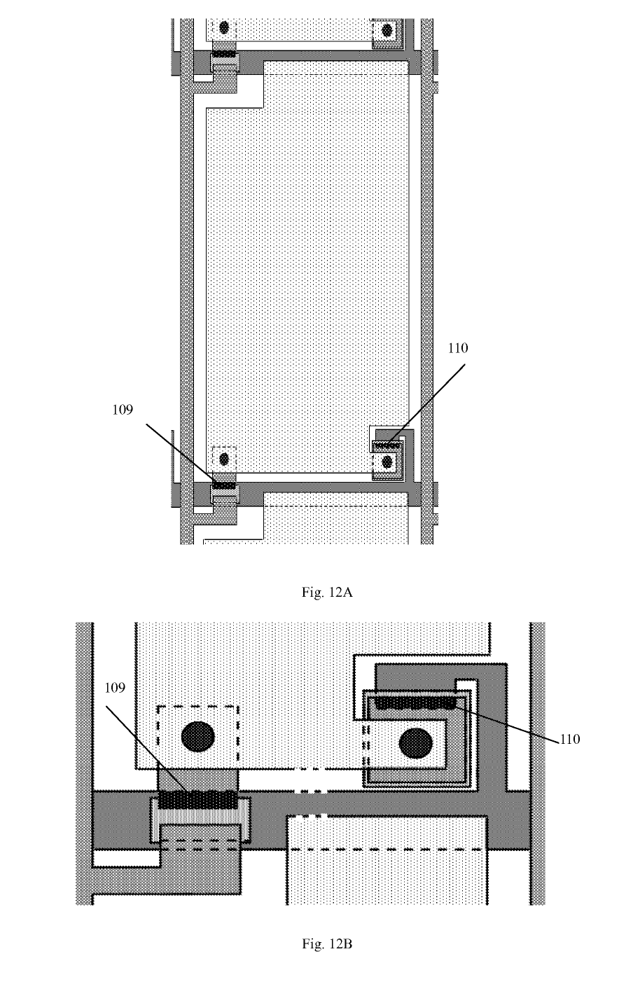

Firstly, a gate metal thin film 1a with a thickness in a range from about 1000 to about 7000 Å is formed on a glass substrate 120, for example, by a magnetron sputtering method. The material for the gate metal thin film 1a usually is selected from the group consisting of Mo, Al, Al-Ni alloy, Mo-W alloy, Cr, Cu and any combination of Mo, Al, Al-Ni alloy, Mo-W alloy, Cr, and Cu. By the exposure and etching process with a mask for the gate electrode, the gate metal thin film are patterned in certain areas of the glass substrate 120 to form gate lines 121, the gate electrode 101, and the compensating gate electrode 115, as shown in FIG. 14. As shown in FIG. 5C, the gate electrode 101 and the compensating gate electrode 115 can have the same thickness and slope after etching.

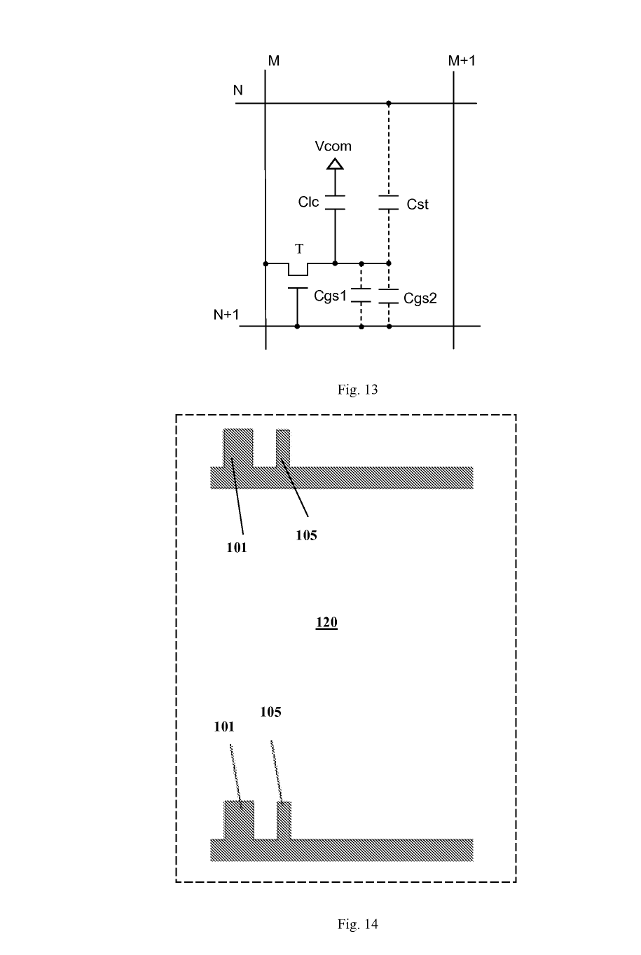

Then, the gate insulating layer thin film 2a with a thickness in a range from about 1000 to about 6000 Å and the active layer thin film 3a with a thickness in a range from about 1000 to about 6000 Å are sequentially deposited on the substrate, for example, by a chemical vapor deposition (CVD) method. The material for the gate insulating layer thin film 2a usually is silicon nitride, and can also include silicon oxide or silicon oxynitride. The material for the active layer thin film 3a is a semiconductor such as amorphous silicon, polycrystalline silicon, and etc. The active layer thin film 3a is exposed and developed with a mask for the active layer, and the active layer thin film 3a is then etched and patterned to form the active layer 103 and the compensating active layer 116, as shown in FIG. 15, in which the active layer 103 overlaps with the gate electrode 101, and the compensating active layer 116 overlaps with the compensating gate electrode 115. The gate insulating layer thin film is used as the gate insulating layer 102. As shown in FIG. 5C, the active layer 103 is integrated with the compensating active layer 116, and the active layer 103 and the compensating active layer 116 have the same thickness and slope after etching, while the gate insulating layer between the gate metal layer and the active layer serves as an etching stop layer.

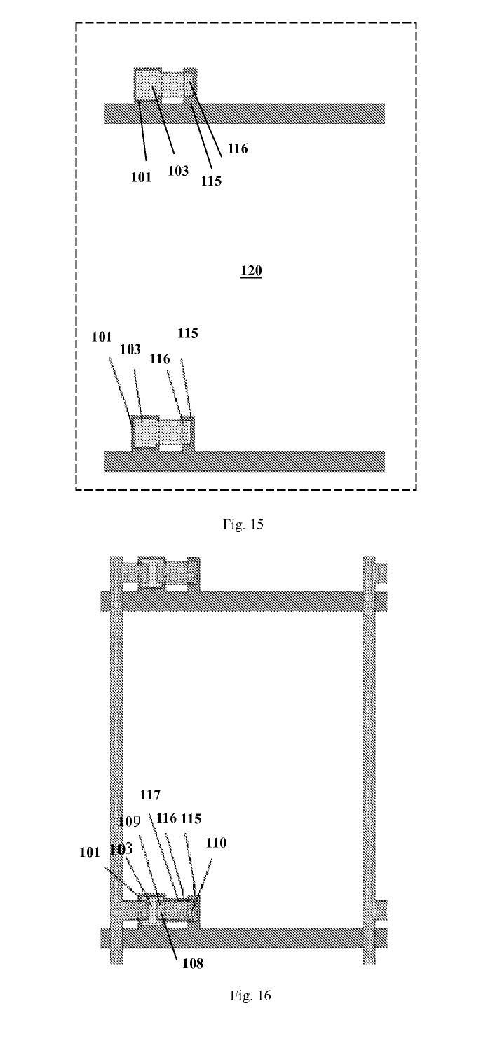

Next, with the similar preparing method as that for preparing the gate metal thin film, the source/drain metal thin film 4a is deposited on the substrate, and has a thickness in a range from about 1000 to about 7000 Å, which is close to that of the gate metal thin film. By the exposure and etching process with a mask for the source/drain electrode, certain areas of the substrate are patterned to form the date lines 104, the drain electrode 107, the source electrode 108, and the compensating source electrode 117. The overlapping region 109 is formed between the gate electrode 101 and the source electrode 108, and forms a parasitic capacitor Cgs1 with the gate insulating layer 102 and the active layer 103 sandwiched therebetween. The overlapping region 110 is formed between the compensating gate electrode 115 and the compensating source electrode 117, and forms a compensating parasitic capacitor Cgs2 with the gate insulating layer 102 and the compensating active layer 116 sandwiched therebetween. The source electrode 108 is integrated with the compensating source electrode 117, as shown in FIG. 16. The drain electrode 107, the source electrode 108 and the compensating source electrode 117 can have the same thickness and slope after etching.

Then, with the similar method as that for preparing the gate insulating layer thin film and the active layer thin film, the passivation layer thin film 5a with a thickness in a range from about 1000 to about 6000 Å is deposited on the whole substrate. The material for the passivation layer thin film 5a is usually silicon oxide. By the exposure and etching process with a mask for the passivation layer, the passivation layer thin film 5a is patterned to form the passivation layer via hole 111 corresponding to the source electrode. Alternatively, additional via hole is formed in the passivation layer corresponding to the compensating source electrode, e.g., as shown in FIG. 7A for the second embodiment.

Lastly, the pixel electrode thin film 6a with a thickness in a range from about 100 to about 1000 Å is deposited on the whole array substrate. The material for the pixel electrode thin film 6a is usually transparent conductive material such as indium tin oxide (ITO), indium zinc oxide (IZO), or aluminum zinc oxide (AZO). By the exposure and etching process with a mask for the transparent electrode, the pixel electrode thin film 6a is patterned to form the pixel electrode 106, in which the pixel electrode 106 is electrically connected to the source electrode 108 and/or the compensating source electrode 117 through the via hole 111 in the passivation layer. The pixel electrode 106 can also be prepared from a metal layer so as to be used for reflective type LCD.

The embodiment described above is an exemplary manufacturing method, which can also be realized by other methods by selecting different materials or the combinations of materials and different photolithography processes such as a 3Mask or a 4Mask process. As for the position and direction of the TFT, and the overlapping between the compensating gate electrode and the compensating source electrode, various modifications and changes are apparent for the device structure of the TFT. All these modifications and changes fall into the scope of the present invention.

Although the above description has been made with a bottom-gate type TFT as the example, it should be appreciated by those skilled in the art that, the embodiments of the present invention can be still applied to a sub-pixel of the TFT-LCD array substrate with a top-gate type TFT. For example, in the top-gate type TFT-LCD array substrate, the gate electrode also can overlap with the source electrode to form a parasitic capacitor. To compensate this parasitic capacitor, a compensating parasitic capacitor can also be provided in the sub-pixel structure, which includes a compensating gate electrode connected to the gate line and a compensating source electrode connected to the pixel electrode. The compensating source electrode is electrically connected to the pixel electrode through a via hole in the passivation layer formed thereon, and this via hole can be either the same as or different from the via hole through which the source electrode is electrically connected to the pixel electrode. Furthermore, the method for preparing a top-gate type transistor is well-known in the art, thus it is not repeated herein for simplicity. In order to form the compensating parasitic capacitor structure, the compensating source electrode can be formed on the substrate simultaneously when the source electrode is formed, the compensating active layer can be formed simultaneously when the active layer is formed, and the compensating gate electrode can be formed simultaneously when the gate electrode is formed.

The invention being thus described, it will be obvious that the same may be varied in many ways. Such variations are not to be regarded as a departure from the spirit and scope of the invention, and all such modifications as would be obvious to those skilled in the art are intended to be included within the scope of the following claims.

What is claimed is:

1. A thin film transistor liquid crystal display (TFT-LCD) array substrate, comprising:
a substrate, on which at least one gate line and at least one data line are formed and cross with each other to define a plurality of sub-pixel regions, wherein one of the plurality of sub-pixel regions includes a thin film transistor (TFT) and a pixel electrode, and the TFT is electrically connected to the pixel electrode; and
a compensating parasitic capacitor structure, comprising a first electrode electrically connected to the gate line and a second electrode electrically connected to the pixel electrode.

2. The array substrate according to claim 1, wherein the TFT comprises:
a gate electrode formed on the substrate and integrated with the gate line;
a gate insulating layer formed on the gate electrode;
an active layer formed on the gate insulating layer;
a source electrode and a drain electrode formed on the active layer and separated apart; and
a passivation layer formed on the source electrode and the drain electrode and with a first via hole formed over the source electrode,
wherein the drain electrode is electrically connected to the data line, and the source electrode is electrically connected to the pixel electrode through the first via hole formed in the passivation layer.

3. The array substrate according to claim 2, wherein the compensating parasitic capacitor structure comprises:
a compensating gate electrode as the first electrode, which is electrically connected to the gate line;
the gate insulating layer and a compensating active layer as a dielectric layer, which are formed sequentially on the compensating gate electrode; and
a compensating source electrode as the second electrode, which is formed on the compensating active layer,
wherein the passivation layer is formed on the compensating source electrode, and the compensating source electrode is electrically connected to the pixel electrode through a second via hole formed in the passivation layer.

4. The array substrate according to claim 3, wherein a first overlapping region between the gate electrode and the source electrode and a second overlapping region between the compensating gate electrode and the compensating source electrode are parallel with each other and have the same width in a parallel direction.

5. The array substrate according to claim 4, wherein the TFT and the compensating parasitic capacitor structure are arranged in a direction perpendicular to or parallel with the gate line.

6. The array substrate according to claim 4, wherein the compensating active layer is integrated with the active layer of the TFT, the compensating source electrode is integrated with the source electrode of the TFT, and the second via hole through which the compensating source electrode and the pixel electrode are connected with each other is the same one as the first via hole through which the source electrode of the TFT and the pixel electrode are connected with each other.

7. The array substrate according to claim 4, wherein the compensating active layer is separated from the active layer of the TFT, the compensating source electrode is separated from the source electrode of the TFT, and the second via hole through which the compensating source electrode and the pixel electrode are connected with each other is different from the first via hole through which the source electrode of the TFT and the pixel electrode are connected with each other.

8. The array substrate according to claim 7, wherein the TFT is formed on the gate line, and a portion of the gate line serves as the gate electrode of the TFT.

9. The array substrate according to claim 3, wherein the compensating gate electrode, the gate electrode and the gate line are made from the same layer.

10. The array substrate according to claim 3, wherein the data line, the source electrode and the drain electrode of the TFT, and the compensating source electrode are made from the same layer.

11. The array substrate according to claim 3, wherein the active layer of TFT and the compensating active layer are made from the same layer.

12. The array substrate according to claim 1, wherein the sub-pixel further comprises a light blocking strip formed on a side of the pixel electrode.

13. The array substrate according to claim 1, wherein the sub-pixel further comprises a common electrode formed under the pixel electrode.

14. The array substrate according to claim 1, wherein the material for the pixel electrode is selected from the group consisting of indium tin oxide, indium zinc oxide, and aluminum zinc oxide.

15. A method of manufacturing a TFT-LCD array substrate, comprising the steps of:
depositing and patterning a gate metal thin film on a substrate to form at least one gate line, a gate electrode of a TFT and a compensating gate electrode being formed with the gate line;
depositing sequentially a gate insulating layer thin film and an active layer thin film, the active layer thin film being patterned to form an active layer and an compensating active layer on the gate electrode and the compensating gate electrode, respectively;
depositing and patterning a source/drain metal thin film to form at least one data line, a drain electrode, a source electrode, and a compensating source electrode, wherein the drain electrode and the source electrode are separated apart with respect to the gate electrode and formed on the active layer, the drain electrode is connected to the data line, and the compensating source electrode is formed over the compensating gate electrode through the gate insulating thin film and the compensating gate electrode;
depositing and patterning a passivation layer thin film to form at least one via hole over the source electrode and the compensating source electrode; and
depositing and patterning a pixel electrode thin film to form a pixel electrode, wherein the pixel electrode is connected to the source electrode and the compensating source electrode through the at least one via hole.

16. The method according to claim 15, wherein a first overlapping region between the gate electrode and the source electrode and a second overlapping region between the compensating gate electrode and the compensating source electrode are parallel with each other and have the same width in a parallel direction.

17. The method according to claim 15, wherein the gate electrode and the compensating gate electrode are connected to the pixel electrode through the same via hole.

18. The method according to claim 15, wherein a light blocking strip on a side of the pixel electrode is formed simultaneously when the gate electrode is formed.

19. The method according to claim 15, wherein a common electrode under the pixel electrode is formed simultaneously when the gate electrode is formed.

20. The method according to claim 15, wherein the pixel electrode is partially formed over the gate line.
